(19) United States
(12) Patent Application Publication
(10) Pub. No.: US 2008/0017116 A1
(43) Pub. Date: Jan. 24, 2008

(54) SUBSTRATE SUPPORT WITH ADJUSTABLE LIFT AND ROTATION MOUNT

(76) Inventors: Jeffrey Campbell, Mountain View, CA (US); Brian H. Burrows, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 11/458,163

(22) Filed: Jul. 18, 2006

(51) Int. Cl. H01L 21/306; C23F 1/00; C23C 16/00

(52) U.S. Cl. 118/729; 156/345.51; 156/345.54; 118/728

(57) ABSTRACT

A method and apparatus for positioning a substrate support within a processing chamber is provided. In one embodiment, an apparatus for positioning a substrate support includes a first portion configured to mount to a bottom of a processing chamber and second portion configured to support a substrate support. The first portion is releaseably coupled to the second portion. The second portion includes a lower housing coupled to a lower collar. The lower collar is laterally positionable relative to the first portion. The lower housing has a planar orientation that is adjustable relative to a planar orientation of the lower collar.

### BACKGROUND OF THE INVENTION

1. Field of the Invention

Embodiments of the present invention generally relate to an adjustable lift and rotation mounting mechanism for controlling the position of a substrate support in a processing chamber.

2. Description of the Related Art

Many semiconductor processing operations, for example, chemical vapor deposition, physical vapor deposition and dry etching, among others, are performed in a vacuum environment. Typically, a substrate is positioned on a movable substrate support disposed within a vacuum processing chamber. The elevation of the substrate support is controlled by a lift mechanism so that the substrate may be disposed at a lower position within the processing chamber to facilitate substrate transfer and an elevated position that typically enhances substrate processing. As the spacing between the top of the processing chamber and the substrate seated on the substrate support may be 200 mils or closer when in the elevated position, the parallelism between the top of the processing chamber and the substrate support is a major attribute in maintaining process uniformity across the width of the substrate and ensuring process repeatability between substrates. For example, if one edge of the substrate is closer to the top of the processing chamber than another edge of the substrate, gases flowing between the substrates and the top of the processing chamber will be inclined to flow predominantly toward the portion of substrate having the widest spacing from the top of the processing chamber, resulting in process non-uniformity across the width of the substrate. Additionally, variations in the distance between the substrate and the top of the processing chamber will typically result in process non-uniformity in plasma enhanced and thermal processes. This is due in part because the intensity of the plasma formed between the substrate and the top of the processing chamber is dependent on the strength of the electrical field defined between the substrate support and the top of the processing chamber, which in turn is dependent on the distance between the substrate support and the top of the processing chamber. If this distance is not uniform, the plasma will not be uniform across the width of the substrate support, resulting in process non-uniformity. As temperature is also dependent on the distance between the heat source and the substrate, uniformity of thermal processes are also dependent of the planar orientation of the substrate support.

Typically, most substrate supports are coupled to their lift mechanisms by an adjustment mechanism that allows for the plane of the substrate support to be adjusted perpendicular to the center line of the processing chamber. However, many adjustment mechanisms utilized to level the substrate support are difficult to secure in a desired position. Furthermore, most adjustment mechanisms are prone to drift during the securing procedure, which is detrimental to processes having tight tolerances for gas flow and plasma uniformity.

Therefore, there is a need for an apparatus for controlling the position of a substrate support.

### SUMMARY OF THE INVENTION

A method and apparatus for positioning a substrate support within a processing chamber is provided. In one embodiment, an apparatus for positioning a substrate support includes a first portion configured to mount to a bottom of a processing chamber and second portion configured to support a substrate support. The first portion is releaseably coupled to the second portion. The second portion includes a lower housing coupled to a lower collar. The lower collar is laterally positionable relative to the first portion. The lower housing has a planar orientation that is adjustable relative to a planar orientation of the lower collar.

In another embodiment, an apparatus for positioning a substrate support includes a chamber mounting ring, a lower collar, a locking member, a lower housing, and an inclination adjuster. The chamber mounting ring is configured to mount to a bottom of a processing chamber. The lower collar is laterally positionable relative to the chamber mounting ring and may be selectively secured relative to the chamber mounting ring by the locking member. The lower housing is coupled to the lower collar and is configured to support a substrate support. The lower housing has a planar orientation that is adjustable relative to a planar orientation of the lower collar by the inclination adjuster

In another embodiment, a method for adjusting the orientation of a substrate support within a processing chamber using a mounting assembly is provided. The mounting assembly includes an upper portion coupled to the processing chamber and a lower portion coupled to the upper portion. The method includes adjusting a lateral position of a collar of the second portion relative to the first portion, and adjusting a planar orientation of the lower housing of the second portion relative to the first portion.

### BRIEF DESCRIPTION OF THE DRAWINGS

A more particular description of the invention, briefly summarized above, may be had by reference to the embodiments thereof that are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a simplified sectional view of a semiconductor processing chamber having a substrate support lift assembly coupled to the processing chamber by a mounting assembly of the present invention;

FIG. 2 is a sectional side view of one embodiment of a mounting assembly;

FIG. 3 is an exploded isometric view of a portion of the mounting assembly illustrating an upper collar and a dome mount;

FIG. 4 is an isometric view of a portion of the mounting assembly illustrating a lower collar; and

FIGS. 5A-B are sectional view of one embodiment of the mounting assembly.

To facilitate understanding, identical reference numerals have been used, wherever possible, to designate identical elements that are common to the figures. It is also contemplated that elements of one embodiment may be advantageously incorporated in other embodiments without further recitation.

### DETAILED DESCRIPTION

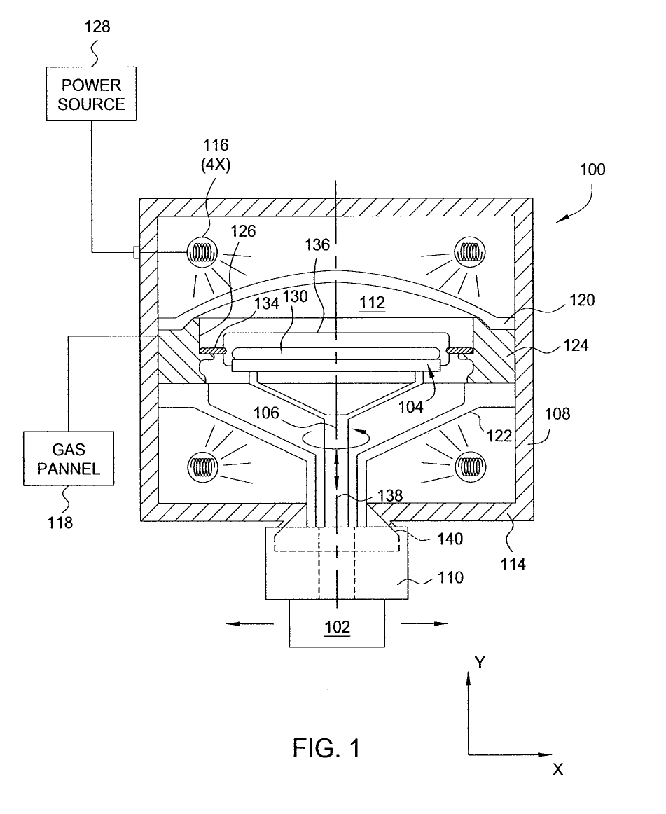

FIG. 1 is a simplified sectional view of a semiconductor processing chamber 100 having a substrate support lift assembly 102 for controlling the elevation of a substrate support 104 disposed within the processing chamber 100. The orientation of the substrate support 104 within the processing chamber 100 is set by a mounting assembly 110 that couples the lift assembly 102 to the chamber 100. The mounting assembly 110 is configured to adjustably control the lateral displacement of the substrate support 104, for example, within the x/z plane, along with adjustably controlling and orientation of the centerline 106 of the substrate support 104 to vertical, e.g., the y-axis shown in the coordinate system shown in FIG. 1. Examples of processing chambers that may be adapted to benefit from the invention include Epi Corona® deposition chambers, available from Applied Materials, Inc. located in Santa Clara, Calif. Although one embodiment of the mounting assembly is illustrated coupled to a polysilicon deposition chamber, the mounting assembly may be utilized in other processing chambers such as physical vapor deposition chambers, etch chambers, ion implant chambers, thermal processing chambers, chemical vapor deposition chambers, atomic layer deposition chambers and plasma processing chambers, among other vacuum processing chambers, wherein control of the planar orientation and lateral position of the substrate support is desirable.

The processing chamber 100 typically includes an annular spacer 124 coupled between an upper quartz dome 120 and a lower quartz dome 122. The spacer 124 and domes 120, 122 define an interior volume 112 of the processing chamber 100. The spacer 124 and domes 120, 122 are disposed in a housing 108. A plurality of radiant heaters 116 are disposed in the housing 108 to heat a substrate 130 disposed in the substrate support 102 through the domes 120,122 of the chamber 100 during processing. A power source 128 is provided to control the amount of energy generated by radiant heaters 116.

A gas panel 118 is coupled to the processing chamber 100 and provides process and/or other gases to the interior volume 112 of the processing chamber 100. In one embodiment, the gas panel 118 is coupled to a port 126 formed through the spacer 124.

The spacer 124 may be fabricated from aluminum or other suitable material. The spacer 124 includes a ledge 132 extending from inner diameter that supports a process kit ring 134. The spacer 124 also has a substrate access port 136 formed therein to facilitate robotic entry and egress of the substrate 130 from the interior volume 112 of the processing chamber 100.

The lift assembly 102 is coupled to the substrate support 104 by a shaft 136. The shaft 136 may be coupled to the lift assembly 102 before or after the lift assembly 104 is coupled to the mounting assembly 110. The lift assembly 102 is configured to adjust the elevation of the substrate support 104 between a transfer position aligned with the substrate access port 136 and a processing position, which in one embodiment, elevates the substrate 130 proximate the upper dome 120 during deposition. The lift assembly 102 is also configured to rotate the substrate support 104 and substrate 130 positioned thereon during processing. Such lift assemblies having rotational and elevational control are conventionally known, and are available from Applied Materials, Inc., among other manufacturers.

A conical dome base 140 extends from a bottom 114 of the housing 108 and provides a mounting surface to which the mounting assembly 110 is coupled. The lift assembly 102 is suspended from the mounting assembly 110. The shaft 138 extends from the lift assembly 102 through the bottom of the housing and the mounting assembly 110 to the substrate support 104. Thus, as the lateral position and inclination of the lift assembly 102 is adjusted by the mounting assembly 110, the motion is transferred by the shaft 138 to the substrate support 104, thereby allowing the lateral position of the substrate support 104, along with the planar orientation of the substrate supporting surface of the substrate support 104 to be tuned and/or set to an orientation that enhances process uniformity.

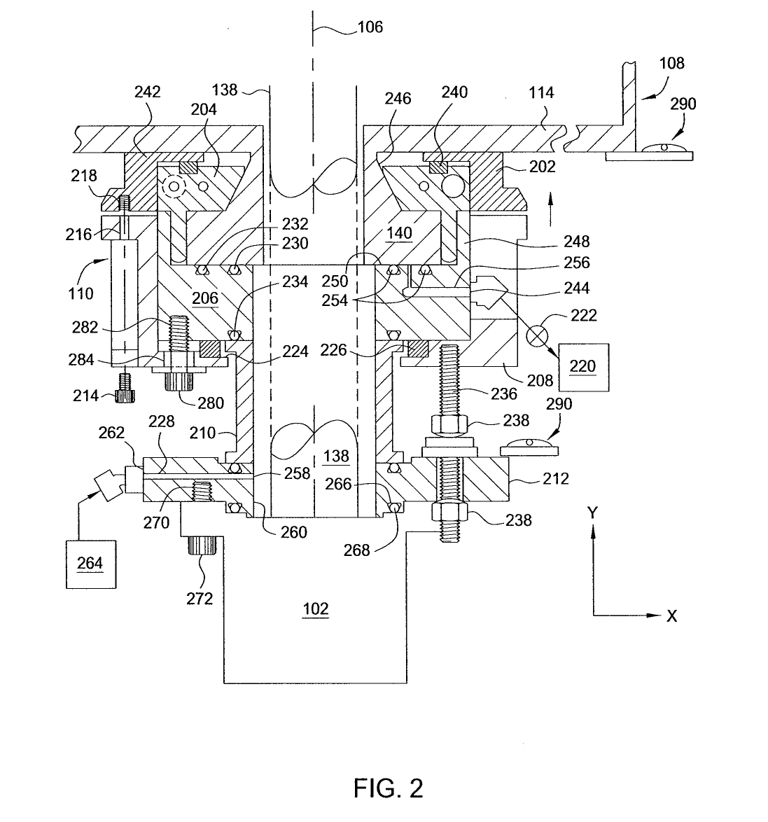

FIG. 2 is a sectional view of one embodiment of the mounting assembly 104. The mounting assembly 104 includes an upper collar 202, a dome mount 204, an upper housing 206, a lower collar 208, a bellows 210 and a lower housing 212. The upper collar 202, dome mount 204, upper housing 206, lower collar 208 and lower housing 212 may be fabricated from a metal or other suitable material. In one embodiment, the upper collar 202, dome mount 204, upper housing 206, lower collar 208 and lower housing 212 are fabricated from stainless steel.

The upper collar 202 and dome mount 204 are coupled to the base 140 of the housing 108 in a generally fixed orientation, while the lower housing is coupled to the lift assembly 102. The upper housing 206 is slip-fit to the dome mount 204 and is captured between the lower collar 208 and the dome mount 204 when the lower collar 208 is coupled to upper collar 202 the lower collar 208 is free to be laterally displaced relative to the dome mount 204 when lower collar 208 and upper housing 206 are loosely fastened, and is secured laterally relative to the dome mount 204 when lower collar 208 and upper housing 206 are tightened together. The lateral displacement of the lower collar 208 moves the centerline 106 of the shaft 138 in the x/z plane laterally as further described below. As the lower collar 208 and upper housing 206 are tightened together, a plurality of seals 230, 232 are compressed to prevent leakage.

The lower housing 212 is coupled to the lower collar 208 by a plurality of threaded standoffs 236, one of which is shown in FIG. 2. At least three threaded standoffs 236 extend from the lower collar 208 in a spaced-apart relation. In one embodiment, the standoffs 236 are spaced equidistant in a polar array about the center of the lower collar 208. A first end of the threaded standoff 236 is secured to the lower collar 208 while a second end passes through the lower housing 212. Spherical nuts 238 secure the position of the lower housing 212 along the length of the threaded standoff 236. The position of the nuts 238 on each of the threaded standoffs 236 sets the inclination of the lower housing 212 in the z/x plane relative to that of the lower collar 208, and ultimately the bottom 114 of the housing 108. As the lower collar 208 is coupled to the lift assembly 102, changes in the inclination of the lower housing 212 is transferred to the lift assembly 102 causing the centerline 106 of the shaft 138 extending from the lift assembly 102 to be adjusted angularly relative to the y-axis. To ease alignment, level indicators 290, such as a bubble level indicator or other device, mounted to the chamber bottom 114 and the lower housing 212 may be comprised to obtain a quick approximation of parallelism. Moreover, the lateral positioning of the lower collar 208 described above is also transferred to the lift assembly 102, causing the centerline 106 of the shaft 138 extending from the lift assembly 102 to be laterally adjusted relative to the z/x plane. Thus, as the lateral and angular orientation of the shaft 136 may be adjusted by the mounting assembly 110, the lateral position of the substrate support 104, along with the inclination of the substrate support 104 relative to the x/z plane may be set to a desired position, for example, such that the substrate support 104 is centered in the spacer 124, and uniformly spaced from the upper dome 120. The bellows 210 disposed between the upper and lower housings 206, 212 allow the inclination of the lower housing 212 to be adjusted while maintaining vacuum integrity.

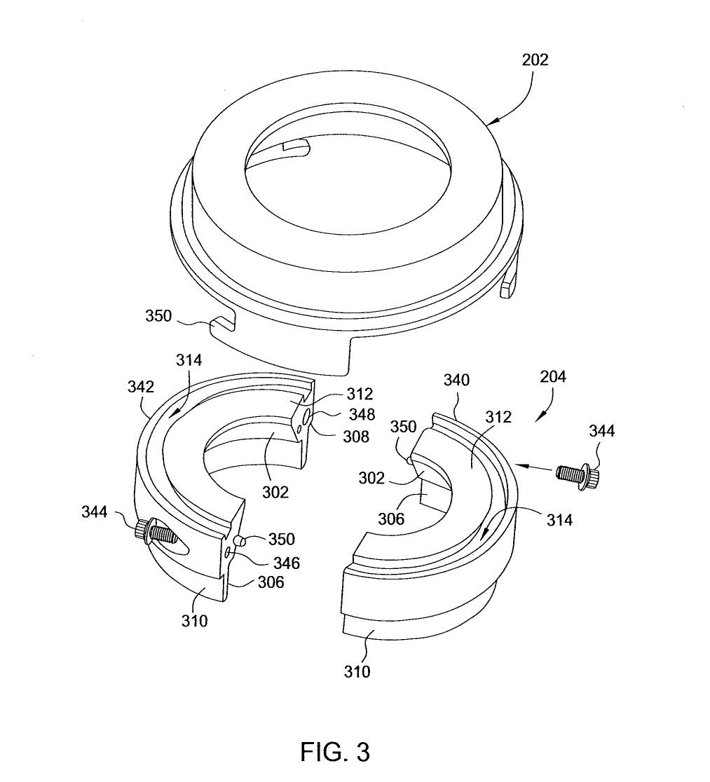

Referring to FIG. 2 and an exploded isometric view of the upper collar 202 and dome mount 204 depicted in FIG. 3, the dome mount 204 includes a tapered section 302 that mates with a tapered section 248 of the base 140. A sleeve 306 extends downward from a bottom 308 of the dome mount 204. An outer diameter 310 of the sleeve 306 is configured to provide a slip fit with a circumscribing lip 248 extending from the upper housing 206. A top 312 of the dome mount 204 includes a groove 314 that accommodates a polymer ring 240 (seen in FIG. 2). The shift-fit ensures the re-alignment of the upper housing 200 and dome mount 204 when the lower portion of the mounting assembly 110 is reattached without significant change in the orientation of the substrate support.

The ring-shaped dome mount 204 has two arc-segment mating sections 340, 342 that have the above features defined therein. The sections 340, 342 have an arc-shape and are secured together by a plurality of fasteners 344. The fasteners 344 extend through a clearance hole 346 defined in one section of the dome mount 204 and engage with a threaded hole 348 formed in the opposite section. Dowel pins 350 utilized to ensure alignment of the holes 346, 348 when coupling the sections 340, 342.

To assemble the dome mount 202 to the base 140, the upper collar 202 is first slid over the base 140. Holding the upper collar 202 clear, the sections 342, 344 are then fastened to clamp the base 140. The tapered surfaces ensure the dome mount 202 cannot slide off the base 140 once the sections 340, 342 are secured together. After the sections 340, 342 are secured to the base 140, the upper collar 202 is dropped over the dome mount 202. A lip 242 prevents the dome mount 204 from sliding through the upper collar 202. A polymer ring 240, positioned between the lip 242 of the upper collar 202 and the dome mount 204 prevent metal to metal contact between the upper collar 202 and the dome mount 204.

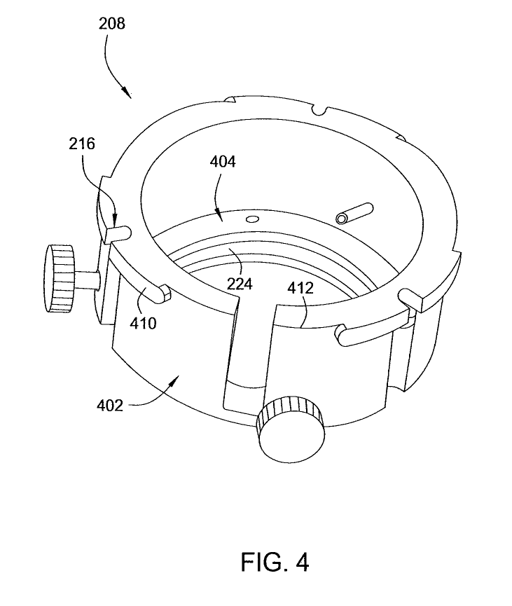

The upper collar 202 is secured the lower collar 208 by a fastening feature that serves as a quick-disconnect. The fastening feature allows the lower half of the mounting assembly 110 that is coupled to the lift assembly 102 to be easily removed from the upper half of the mounting assembly 110 that is coupled to the base 140 of the housing 108, thereby facilitating removal of the substrate support and/or lift assembly for maintenance. The fastening feature may be a mating threaded section, bolts, clamps or other feature suitable for coupling the collars 202, 208. In the embodiment depicted in FIGS. 2-3, the fastening feature is a push-and-twist fitting that includes a catch 350 extending from a lower surface of the upper collar 202, which can be rotated to engage with a tab 410 extending outward from an outer diameter 412 of the lower collar 208, as shown in FIG. 4. Examples of push-and-twist fittings include quarter turn fasteners, pawl latches, bayonet fittings and the like.

Referring primarily to FIG. 2, the upper housing 206 includes a recessed surface 250 circumscribed by the lip 248. The recessed surface 250 mates with a bottom 252 of the base 140. A pair of seal glands 254 are formed in the recessed surface 250 to accommodate the seals 230, 232. The seals 230, 232 may be fabricated from a fluoroelastomer, or other suitable material.

A passage 256 is formed through the upper housing 206. One end of the passage 256 is in fluid communication with a portion of the recessed surface 250 defined between the seal glands 254. A second end of the passage 254 terminates in a port 244 that facilitates coupling the passage to a vacuum source 220. A sensor 222 is coupled between the vacuum source 220 and port 244 to enable detection of leakage of the seal 230.

Referring now to FIG. 2 and an isometric view of the lower collar 208 depicted in FIG. 4, the lower collar 208 has a generally cylindrical form. The lower collar 208 includes a sidewall 402 coupled to a bottom 404 as a lower end. The bottom 404 has a center hole to accommodate passage of the shaft 138. The upper end of the sidewall 402 has tabs 410 extending from the outer diameter 412 of the sidewall 402 that engage the catch 350 of the upper housing 202. A fastener 214, disposed through a slot or hole 216 in the lower collar 208 and engaged in a threaded hole in the upper collar 202, may be utilized to prevent the collars 202, 208 from rotating once the push-and-twist fitting has been engaged.

The bottom 404 of the lower collar 208 includes a step 224. The step 224 retains an annular bearing 226 disposed between the lower collar 208 and the upper housing 206. The bearing 226 may be fabricated from a polymer to prevent contact between the metal surfaces as the lower collar 208 slides laterally relative to the upper housing 206. In one embodiment, the bearing 226 may be fabricated from polyetheretherketone (PEEK), PTFE or other suitable low friction polymer

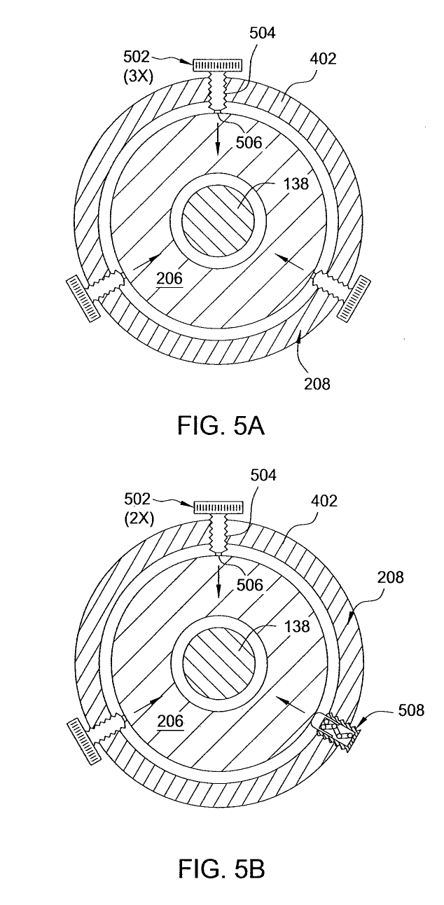

FIG. 5A is a sectional view of the upper housing 206 the lower collar 208 illustrating one embodiment of an adjustment mechanism suitable for positioning the lower collar 208 laterally relative to the upper housing 206. In the embodiment depicted in FIG. 5A, at least two adjustment screws 502 are threaded through respective threaded holes 504 formed in the sidewall 402 of the lower collar 208. The adjustment screws 502 are generally arranged in a polar array, with a distal end 506 facing the center of the lower collar 208. Each adjustment screw 502 may be rotated such that the distal end 506 of the adjustment screw 502 contacts against the upper housing 206 and urges the lower collar 208 relative thereto in a respective direction. The distal end 506 of the adjustment screw 502 may have a polymer and/or ball tip to minimized particle generation. Since the upper housing 206 is slip fit over the dome mount 204, the position of the upper housing 206 is fixed relative to the housing 108. Thus, as the adjustment screws 502 are turned, the lower collar 208 (with lift assembly 102 and substrate support 104 coupled thereto) are moved laterally relative to the upper housing 206. In the embodiment depicted in FIG. 5A, three adjustment screws 502 are utilized. In embodiment depicted in FIG. 5B, two adjustment screws 502 and at least one spring plunger 508 are utilized. The spring plunger 508 proves a force that maintains the upper housing 206 against the adjustment screws 502.

Once the relative positions of the lower collar 208 and the upper housing assembly 206 are adjusted to a desired position, the lower collar 208 is secured to the upper housing assembly 206 utilizing a plurality of fasteners 280. The fasteners 280 extend through an oversized hole 284 formed through the bottom of the lower collar 208 and engage a threaded hole formed in the upper housing 206. The oversized hole 208 is configured to accommodate the laterally movement of the fastener 280 within the hole 284 as the lower collar 210 is adjusted relative to the upper housing 206. Once the fasteners 280 is tightened, the bearing 226 and seal 234 are clamped, creating a gas tight passage.

Referring back to FIG. 2, the lower housing 212 is sealingly coupled to the bellows 210 on a first side and coupled to the lift assembly 102 on a second side. A seal gland 266 is formed on the second side of the lower housing 212 to accommodate a seal 268 that provides a seal between the lower housing 212 and lift assembly 102. The seal 268 is compressed by fasteners 272 engage a threaded hole 270 formed in the lower housing 212 to secure the lower housing 212 to the lift assembly 102.

A passage 228 is formed through the lower housing 212, fluidly coupling a port 262 formed in the exterior of the lower housing 212 to an hole 258 formed in the inside diameter 260 of the lower housing 212. The port 262 is coupled to a gas source 264 that provides a purge gas, such as nitrogen, into the interior passage formed through the mounting assembly 110 that eventually flows into the interior volume 112 of the processing chamber 100.

Thus, a mounting assembly 110 has been disclosed that facilitates maintaining uniform spacing between the upper dome 120 and the substrate supporting surface of the substrate support 104 which promotes process uniformity and repeatability. The invention also improves the ease in setting the concentricity between the substrate support 104 and the walls bounding the interior volume 112, thereby enhancing the uniformity of gas flow around the perimeter of the substrate support 104. In another aspect of the invention, the quick disconnect features defined between the upper and lower collars 202, 208 allow the substrate support 104 to be detached and reconnected to the processing chamber while substantially retaining its original alignment since the alignment features controlling the orientations of the upper and lower housings relative to the lower collar are not disturbed.

While the foregoing is directed to the preferred embodiment of the present invention, other and further embodiments of the invention may be devised without departing from the basic scope thereof, and the scope thereof is determined by the claims that follow.

1. An apparatus for positioning a substrate support, comprising:
a first portion configured to mount to a bottom of a processing chamber;
a second portion configured to support a substrate support and releaseably coupled to the first portion, the second portion further comprising:
a lower collar having a position laterally adjustable relative to the first portion; and
a lower housing coupled to the lower collar, the lower housing having a planar orientation adjustable relative to a planar orientation of the lower collar.

2. The apparatus of claim 1, wherein the first portion further comprises:
a dome mount having a tapered inner surface.

3. The apparatus of claim 2, wherein the tapered inner surface further comprises:
a plurality of sections coupled together and forming a ring.

4. The apparatus of claim 2, wherein the first portion further comprises:
an upper collar having a flange extending over an upper portion of the dome mount.

5. The apparatus of claim 1 further comprising:
a push-and-twist fitting coupling the first and second portions.

6. The apparatus of claim 1, wherein the second portion further comprises:
an upper housing slip fit to the upper portion.

7. The apparatus of claim 6, wherein the lower collar retains the upper housing against the upper portion.

8. The apparatus of claim 6 further comprising:
a polymer bearing disposed between the lower collar and the upper housing.

9. The apparatus of claim 6, wherein the second portion further comprises:
a mechanism for locking the position of the lower collar relative to the upper housing.

10. The apparatus of claim 6, wherein the upper housing further comprises:
an upper surface having at least two seal glands formed therein; and
a passage fluidly coupling a region of the upper surface defined between the glands and an exterior of the upper housing.

11. The apparatus of claim 6, wherein the second portion further comprises:
a bellows coupled between the upper and lower housings.

12. The apparatus of claim 6, wherein the second portion further comprises:
a plurality of threaded members coupling the lower housing and lower collar in a spaced-apart relation.

13. The apparatus of claim 12 further comprising:
a plurality of spherical fasteners securing the planar orientation of the lower housing on the threaded members.

14. The apparatus of claim 16 further comprising:
a plurality of adjustment screws engaging the upper housing and the upper collar, wherein an orientation of each screw is configured to urge the upper housing relative to the upper collar in different lateral directions.

15. The apparatus of claim 14 further comprising:
a least one spring plunger urging the upper housing towards a center of the upper collar.

16. An apparatus for positioning a substrate support, comprising:
a chamber mounting ring configured to mount to a bottom of a processing chamber;
a lower collar laterally positionable relative to the chamber mounting ring;
a locking member for selectively securing the collar relative to the chamber mounting ring;
a lower housing coupled to the lower collar and configured to support a substrate support, the lower housing having a planar orientation adjustable relative to a planar orientation of the lower collar; and
an inclination adjuster coupling the lower housing to the lower collar.

17. The apparatus of claim 16, wherein the inclination adjuster further comprises:
a plurality of threaded members coupling the lower housing and lower collar in a spaced-apart relation; and
a plurality of spherical fasteners securing the planar orientation of the lower housing on the threaded members.

18. The apparatus of claim 16 further comprising:
an annular upper housing slip fit to the chamber mounting ring, wherein the lower collar is laterally positionable relative to the upper housing and chamber mounting ring.

19. The apparatus of claim 18, wherein the locking member further comprises:
at least one fastener disposed through the lower collar and coupled to the upper housing.

20. An apparatus for positioning a substrate support, comprising:
a chamber mounting ring configured to mount to a bottom of a processing chamber;
an upper collar circumscribing the chamber mounting ring;
an upper housing slip fit with the chamber mounting ring;
a lower collar circumscribing the upper housing, the lower collar laterally positionable relative to the upper housing;
a tab and catch releaseably securing the upper and lower collars;
a polymer bearing proving a sliding bearing surface between the upper collar and upper housing;
a lower housing coupled to the lower collar and configured to support a substrate support;
a bellows sealingly coupling the upper and lower housings; and
an inclination adjuster configured to selectively adjust a planar orientation of the lower housing relative to a planar orientation of the lower collar.

21-41. (canceled)
